(19) United States
(12) Patent Application Publication
(10) Pub. No.: US 2002/0109183 A1
(43) Pub. Date: Aug. 15, 2002

(54) Field-effect semiconductor device

(75) Inventors: Youichi Ishimura, Tokyo (JP); Yoshifumi Tomomatsu, Fukuoka (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Chiyoda-ku (JP)

(21) Appl. No.: 09/881,675

(22) Filed: Jun. 18, 2001

(30) Foreign Application Priority Data
Dec. 13, 2000 (JP) 2000-378796

(51) Int. Cl. H01L 29/76; H01L 29/94; H01L 31/062; H01L 31/113; H01L 31/119

(52) U.S. Cl. 257/335

(57) ABSTRACT

A field-effect semiconductor device having a semiconductor layer of a first conductivity type, a collector region of a second conductivity type that is formed beneath the semiconductor layer and equipped with a collector electrode on its lower surface, a base region of the second conductivity type that is formed as part of the upper surface of the semiconductor layer, at least one pair of emitter regions of the first conductivity type that are formed as part of the upper surface of the base region, an insulating layer that is formed to contact the base region that is located between the emitter regions and the semiconductor layer, a gate electrode that is placed on the upper surface of the insulating layer, an interlayer insulating film that is formed to cover the gate electrode, a barrier metal layer that is formed to continuously contact the interlayer insulating film, base region, and emitter region, and an emitter electrode that is formed on the upper surface of the barrier metal layer. The barrier metal layer that is formed between the emitter electrode and the interlayer insulating film comprises a layer containing nitrogen.

### BACKGROUND OF THE INVENTION

The present invention relates to a field-effect semiconductor device having a MOS gate.

Of recent years, inverterization in industrial apparatus and electric home appliances has been in rapid progress in order to save energy. A well-known device suitable for such purposes is an insulated-gate bipolar transistor, abbreviated as IGBT hereafter. The IGBT is a kind of MOSFET (MOS field-effect transistor) in that a p-layer is added to the drain of a MOSFET and minority carriers are injected through it to obtain lower ON-resistance. Therefore, the IGBT is a useful power device that has advantages for MOSFET, such as gate-voltage activation, high-speed switching characteristics, and durability.

FIG. 6 is a vertical cross-sectional view that illustrates the schematic structure of a conventional IGBT. In this IGBT 40, an n⁺-buffer layer 43 and an n⁻ layer 42 are successively formed on a p⁺-collector layer 44 that comprises a p⁺-semiconductor substrate. Also, a p-base region 46 is formed as part of the upper surface of the n⁻ layer 42. Further, high-density impurities of n type are selectively diffused to form an n⁺-emitter region 47 as part of the upper surface of the p-base region 46. The area that is part of the surface region of the p-base region 46 and is located between the n⁻ layer 42 and the n⁺-emitter region 47 forms a channel region, and a gate electrode 49 is formed on the channel region through an insulating layer 48. And an interlayer insulating film 51 is formed to cover the gate electrode 49. Further, an emitter electrode 53 is formed to cover the interlayer insulating film 51 and contact the upper surfaces of the p-base region 46 and the n⁺-emitter region 47. Also, a collector electrode 45 is formed on the lower surface 44aof the p⁺-collector layer 44.

The operation of IGBT 40 is described in the following. The Application of a positive voltage to the gate electrode 49 forms a channel region that is inverted to n type in the upper surface of the p-base region 46, which is beneath the gate electrode 49, so that electrons are injected from the n⁺-emitter region 47 into the n⁻ layer 42 through the n-type channel. At the same time, positive holes are injected from the p⁺-collector layer 44 into the n⁻ layer 42 as minority carriers, so that the n⁻ layer 42 undergoes a conductance modulation to produce an advantage of comparatively low current resistance in the n⁻ layer 42.

In this IGBT 40, a parasitic thyristor is inevitably generated, therefore it is desirable that the pinch resistance of the p-base region 46, which is beneath the n⁺-emitter layer 47, is lowered to obtain a great amount of breakdown withstanding.

Also, in IGBT 40, in order to use it in high frequency, switching speed is adjusted by performing lifetime control. For this lifetime control method, there are, for example, diffusion of heavy metal such as platinum and ion irradiation such as electron beam irradiation. With using electron beam irradiation, the IGBT is treated with annealing processing in order for its performance not to vary after an appropriate quantity of electron beams were irradiated, even if an additional heat load is added in the production process.

In the electron beam irradiation, the intersurface level of the gate insulating film 48 changes, so that the threshold voltage changes as follows. For example, if the threshold voltage before electron beam irradiation is Vₜₕ1, the threshold voltage after electron beam irradiation is Vₜₕ2, and the threshold voltage after annealing processing is Vₜₕ3, then the following relationships can be obtained.

Vₜₕ1>Vₜₕ2,

Vₜₕ2>Vₜₕ3,

Vₜₕ1>Vₜₕ3.

As seen from these inequalities, the final threshold voltage becomes lower than the one before electron beam irradiation, so that the current density in the p-base region 46 can be raised. That is, the pinch resistance of the p-base region 46, which is beneath the n⁺-emitter region 47, can be lowered, so that an IGBT having a great amount of breakdown withstanding can be realized.

The object of the present invention is to provide an insulated gate bipolar transistor that can realize a greater amount of breakdown withstanding without adding any complex production process.

### SUMMARY OF THE INVENTION

In an aspect of the present invention, there is provided a field-effect semiconductor device having a semiconductor layer of a first conductivity type, a collector region of a second conductivity type that is formed beneath said semiconductor layer and equipped with a collector electrode on its lower surface, a base region of the second conductivity type that is formed as part of the upper surface of said semiconductor layer, at least one pair of emitter regions of the first conductivity type that are formed as part of the upper surface of said base region, an insulating layer that is formed to contact said base region that is located between said emitter regions and said semiconductor layer, a gate electrode that is placed on the upper surface of said insulating layer, an interlayer insulating film that is formed to cover said gate electrode, a barrier metal layer that is formed to continuously contact said interlayer insulating film, base region, and emitter regions, and an emitter electrode that is formed on the upper surface of said barrier metal layer, characterized in that said barrier metal layer that is formed between said emitter electrode and said interlayer insulating film comprises a layer containing nitrogen. Said barrier metal layer that is formed between said emitter electrode and said interlayer insulating film may comprise titanium nitride. The thickness of said barrier metal layer may be more than 40 nm. The impurity density of said interlayer insulating film may be less than 5 mol %. Said emitter electrode may comprise aluminum.

### BRIEF DESCRIPTION OF THE DRAWINGS

Other objects and attainments together with a fuller understanding of the invention will become apparent and appreciated by referring to the following description and claims taken in conjunction with the accompanying drawings, in which like parts are designated by like reference numerals and in which:

FIG. 1 is a vertical cross-sectional view that schematically shows the structure of an insulated gate bipolar transistor (IGBT) in accordance with a first embodiment of the present invention;

FIG. 2 is a graph that shows the changes in threshold voltage due to electron beam irradiation and annealing processing for an IGBT in accordance with the first embodiment;

FIG. 3 is a graph that represents the relationship between p-base density and threshold voltage for an IGBT in accordance with the first embodiment;

FIG. 4 is a graph that represents the relationship between the content of Si (silicon) contained in Al (aluminum) and the rate of changes in contact resistance for an IGBT in accordance with a second embodiment of the present invention;

FIG. 5 is a graph that represents the relationship between the film thickness of the barrier metal layer and contact resistance for an IGBT in accordance with a third embodiment of the present invention;

FIG. 6 is a vertical cross-sectional view that schematically shows the structure of a conventional insulated gate bipolar transistor.

### DESCRIPTION OF THE PREFERRED EMBODIMENTS

In the following are described some embodiments of the present invention with reference to the attached figures.

First Embodiment:

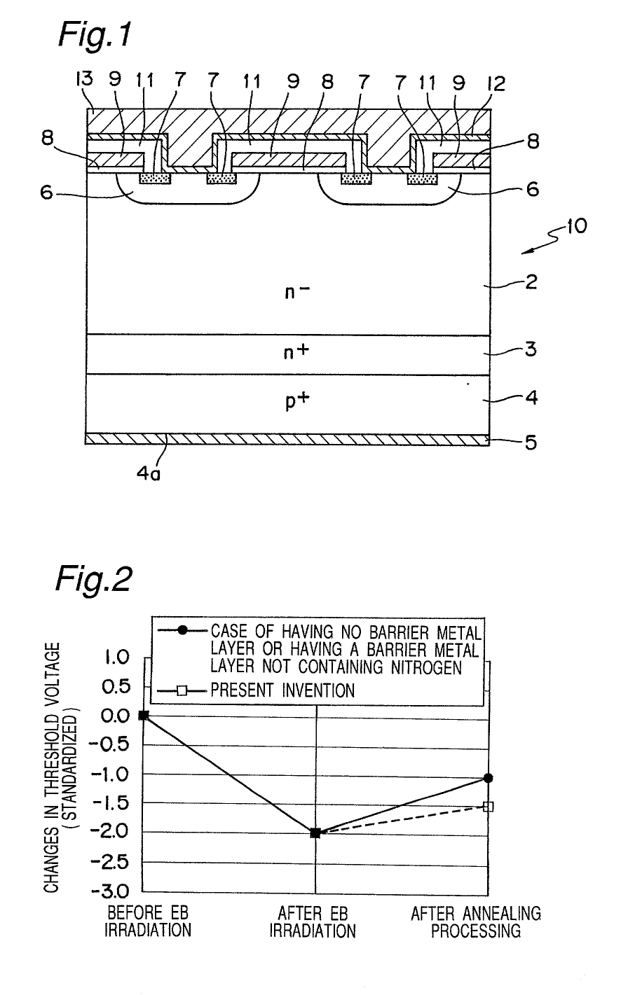

FIG. 1 is a vertical cross-sectional view that schematically shows the structure of an insulated gate bipolar transistor (abbreviated as IGBT hereafter) in accordance with a first embodiment of the present invention. In this IGBT 10, an n⁺-buffer layer 3 and an n⁻ layer 2 are successively formed on a p⁺-collector layer 4 that consists of a p⁺-semiconductor substrate. Also, a p-base region 6 is formed as part of the upper surface of the n⁻ layer 2. Further, high-density impurities of n type are selectively diffused to form n⁺-emitter regions 7 as part of the upper surface of the p-base region 6. The part of the surface region of the p-base region 6 which is located between the n⁻ layer 2 and the n⁺-emitter regions 7 forms a channel region, and a gate electrode 9 is formed on the channel region through an insulating layer 8. And an interlayer insulating film 11 is formed to cover the gate electrode 9.

Further, in this IGBT 10, a barrier metal layer 12 is formed to continuously contact the interlayer insulating film 11, base region 6, and emitter regions 7. Also, an emitter electrode 13 is formed to cover the interlayer insulating film 11 and to contact the upper surfaces of the p-base region 6 and the n⁺-emitter regions 7. Also, a collector electrode 5 is formed on the lower surface 4a of the p⁺-collector layer 4.

The operation of IGBT 10 is described in the following. The application of a positive voltage to the gate electrode 9 forms a channel region that is inverted to n-type in the upper surface of the p-base region 6, which is beneath the gate electrode 9, so that electrons are injected from the n⁺-emitter regions 7 into the n⁻ layer 2 through the n-type channel. A the same time, positive holes are injected from the p⁺-collector layer 4 into the n⁻ layer 2 as minority carriers, so that a conductance modulation occurs in the n⁻ layer 2 to produce an advantage of comparatively low current resistance in the n⁻ layer 2.

In this way, IGBT 10 basically performs bipolar operation. This IGBT 10 is an element that base-drives the transistor section composed of the p⁺-collector layer 4, n⁻ layer 2, and p-base layer 6 by means of the MOSFET section composed of the gate electrode 9, insulating layer 8, and p-base region 6.

In this first embodiment, the barrier metal layer 12 between the interlayer insulating film 11 and emitter electrode 13 consists of a layer containing nitrogen. Among methods of forming this barrier metal layer 12, a commonly known method in the LSI production technology and the like can be used. For example, the barrier layer can be easily formed by sputtering in a nitrogen atmosphere or by annealing in a nitrogen atmosphere after sputtering.

FIG. 2 is a graph that shows the changes in the threshold voltage due to electron beam irradiation and annealing processing. This graph schematically illustrates experimentally obtained results for a case of having no barrier metal layer or having a barrier metal layer not containing nitrogen and for a case of having a barrier metal layer containing nitrogen. The results are changes in the threshold voltage, from the threshold voltage Vₜₕ1 before electron beam irradiation for lifetime control, through the threshold voltage Vₜₕ2 after the electron beam irradiation, to the threshold voltage Vₜₕ3 after annealing processing. The following Table 1 shows the actual values used for drawing the graph of FIG. 2.

TABLE 1

| | Case of having no | |
|---|---|---|
| | barrier metal layer or | Case of having a |
| | having a barrier metal | barrier metal layer |
| | layer not containing | containing nitrogen |
| | nitrogen | (present invention) |
| Before | 0.0 | 0.0 |
| electron | | |
| beam (EB) | | |
| irradiation | | |
| After | −2.0 | −2.0 |
| electron | | |
| beam (EB) | | |
| irradiation | | |
| After | −1.0 | −1.5 |
| annealing | | |
| processing | | |

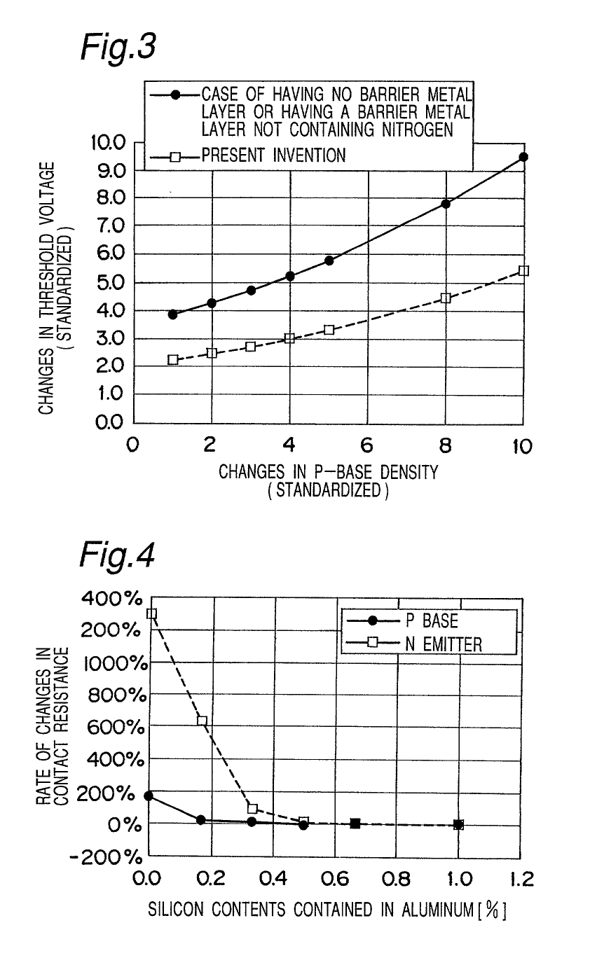

Also, FIG. 3 is a graph that represents the relationship between the p-base density and the threshold voltage after annealing processing with reference to Table 2. Here, experimentally obtained results for the case of having no barrier metal layer or having a barrier metal layer (TiW) not containing nitrogen and for the case of having a barrier metal layer (TiN) containing nitrogen are the graph. The following Table 2 shows the actual values used to draw the graph of FIG. 3.

TABLE 2

| | Case of having no | |
|---|---|---|
| | barrier metal layer | Case of having a |
| | or having a barrier | barrier metal layer |
| | metal layer not | containing nitrogen |
| p-base density | containing nitrogen | (present invention) |
| 1 | 3.9 | 2.21 |
| 2 | 4.3 | 2.44 |
| 3 | 4.7 | 2.70 |
| 4 | 5.2 | 2.98 |
| 5 | 5.8 | 3.30 |
| 8 | 7.8 | 4.45 |
| 10 | 9.5 | 5.44 |

As seen from the graph of FIG. 3, in the first embodiment, p-base density can be raised to obtain the same threshold voltage by forming a barrier metal layer containing nitrogen. As a result, the pinch resistance of the p-base region immediately beneath the n⁺-emitter regions can be lowered, so that an IGBT having a greater amount of breakdown withstanding can be provided.

Second Embodiment.

An IGBT in accordance with a second embodiment of the present invention is basically structured as same as that of the above first embodiment. However, pure aluminum (Pure-Al) is used for the material of the emitter electrode. Conventionally, for example, an aluminum alloy containing silicon (Al—Si) has been used for the material of the emitter electrode. However, of recent years, improvement in junction strength between the wire bond and the semiconductor has been necessary. Also, in almost all cases, wires are bonded directly on IGBT cells in an IGBT, to raise IGBT cell density in a chip. In an IGBT that uses an aluminum alloy for the material of the emitter electrode, excessive silicon contained therein is precipitated, so that during wire bonding, stress is concentrated on the precipitation nucleus, and thereby, there is some apprehension that defectiveness originating from the precipitation nucleus may be produced.

On the other hand, when pure aluminum is used for the material of the emitter electrode in an IGBT as in the present second embodiment, precipitation nucleus of silicon are not produced, but there occurs a case where ohmic contacts fail by reacting with silicon itself (aluminum spikes). FIG. 4 is a graph that represents the relationship between the content of Si (silicon) and contact resistance in the p-base region 6 and n-emitter regions 7 in the case of having no barrier metal layer to show the relationship between aluminum spikes and contact resistance. The next Table 3 shows the referred values used to draw the graph of FIG. 4.

TABLE 3

| Content of | | |
|---|---|---|
| silicon in | Contact resistance and rate of its changes | |
| Al (%) | P-base | n-emitter |

| | | | | |
|---|---|---|---|---|
| 0.000 | 55.1 | 170.1% | 107.08 | 1294.3% |
| 0.167 | 24.2 | 18.6% | 55.48 | 622.4% |
| 0.333 | 22.6 | 10.8% | 14.64 | 90.6% |
| 0.500 | 18.9 | −7.4% | 8.35 | 8.7% |
| 0.667 | 20.0 | −2.0% | 7.88 | 2.6% |
| 1.000 | 20.4 | 0.0% | 7.68 | 0.0% |

As seen from the graph of FIG. 4, if a certain amount of Si is not contained, aluminum spikes occur. In addition, a similar description is given by Japanese Laid-open Patent publication H11-284176. Therefore, the above phenomenon is common, but in the second embodiment of the present invention, a great amount of breakdown withstanding is obtained by forming a nitride barrier metal layer in addition to the effects disclosed in the above publication.

Third Embodiment.

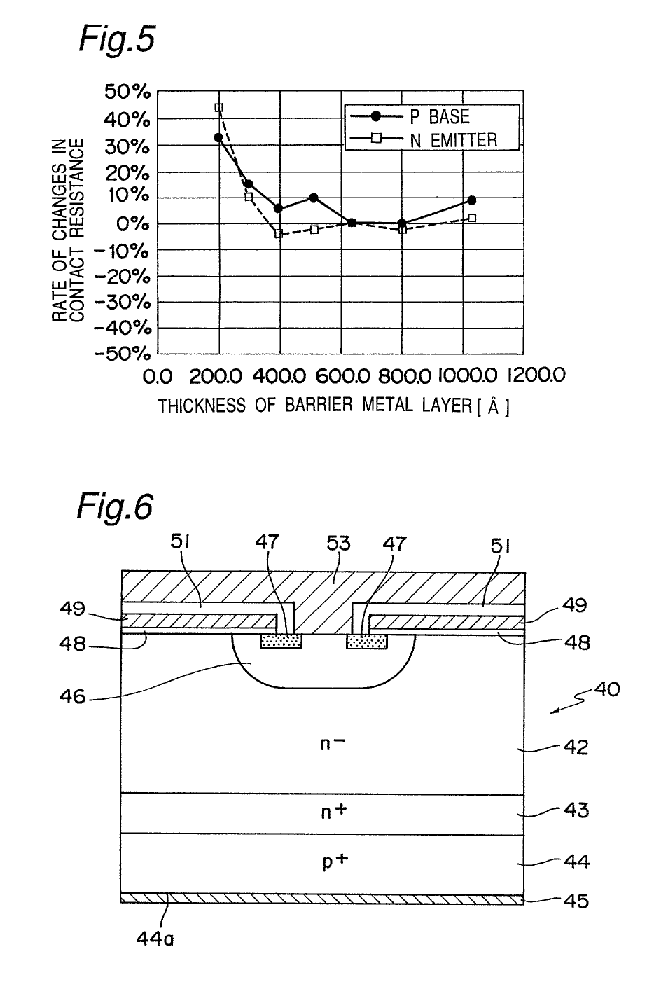

FIG. 5 represents the relationship between the film thickness of the barrier metal layer 12 and contact resistance, relating to an IGBT in which pure aluminum is used for the material of the emitter electrode 13 (see FIG. 1), as described in the above second embodiment. The barrier metal layer 12 is made of titanium nitride which is treated by annealing processing in a nitrogen atmosphere after titanium sputtering. Table 4 shows the referred values used to draw the graph of FIG. 5.

TABLE 4

| Film | | |
|---|---|---|
| thickness | | |
| of barrier | | |
| metal | Contact resistance and rate of its changes | |
| layer (A°) | P-base | n-emitter |

| | | | | |
|---|---|---|---|---|
| 198 | 28.76 | 33.0% | 10.33 | 43.5% |
| 297 | 24.87 | 15.0% | 7.92 | 10.3% |
| 394 | 22.8 | 5.4% | 6.89 | −4.3% |
| 512 | 23.68 | 9.5% | 7.00 | −2.8% |
| 635 | 21.63 | 0.0% | 7.20 | 0.0% |
| 800 | 21.53 | −0.5% | 7.00 | −2.8% |
| 1031 | 23.48 | 8.6% | 7.33 | 1.8% |

As seen from the graph of FIG. 5, large amounts of changes in the contact resistance appear at the film thickness 40 nm of the barrier metal layer 12. That means the barrier metal layer should be formed with its thickness or over in order to obtain the sufficient functionality of a barrier in the barrier metal layer 12. Thus, the stability of the device can be secured by obtaining the sufficient functionality of a barrier in the barrier metal layer 12.

Fourth Embodiment.

Further, as described in the above second embodiment, relating to an IGBT where pure aluminum is used as the material of emitter electrode 13, and a barrier metal layer of titanium nitride is formed by annealing processing in a nitrogen atmosphere after titanium sputtering, when we assigned the impurity densities (e.g. phosphorus density) in the interlayer insulating film 11 (see FIG. 1) to examine the wire bond, we confirmed that the junction strength between the interlayer insulating film 11 and barrier metal layer 12 declined as the impurity densities become more than 5 mol %.

From this observation, it is preferable that the interlayer insulating film 11 be formed so that its impurity density should not become more than 5 mol %. Further, if the impurity density is more than 5 mol %, then it is necessary that a non-doped interlayer insulating film be formed on the interlayer insulating film 11.

Thus, the stability of the device can be improved by forming the interlayer insulating film 11 in such way as its impurity density does not exceed 5 mol %, and sufficient junction strength between the interlayer insulating film 11 and barrier metal layer 12 is obtained.

Finally, it is obvious that the present invention is not limited to the embodiments described above, and various kinds of modifications and changes in designing may be possible without departing from the scope of the present invention. For example, power semiconductor devices having the MOS structure as their capacitor structure were described in the foregoing embodiments, but the present invention can be applied to power semiconductor having the trench structure.

What is claimed is:

1. A field-effect semiconductor device having a semiconductor layer of a first conductivity type, a collector region of a second conductivity type that is formed beneath said semiconductor layer and equipped with a collector electrode on its lower surface, a base region of the second conductivity type that is formed as part of the upper surface of said semiconductor layer, at least one pair of emitter regions of the first conductivity type that are formed as part of the upper surface of said base region, an insulating layer that is formed to contact said base region that is located between said emitter regions and said semiconductor layer, a gate electrode that is placed on the upper surface of said insulating layer, an interlayer insulating film that is formed to cover said gate electrode, a barrier metal layer that is formed to continuously contact said interlayer insulating film, base region, and emitter regions, and an emitter electrode that is formed on the upper surface of said barrier metal layer, characterized in that said barrier metal layer that is formed between said emitter electrode and said interlayer insulating film comprises a layer containing nitrogen.

2. The field-effect semiconductor device according to claim 1, wherein said barrier metal layer that is formed between said emitter electrode and said interlayer insulating film comprises titanium nitride.

3. The field-effect semiconductor device according to claim 1, wherein the thickness of said barrier metal layer is more than 40 nm.

4. The field effect semiconductor device according to claim 1, wherein the impurity density of said interlayer insulating film is less than 5 mol %.

5. The field-effect semiconductor device accroding to claim 1, wherein said emitter electrode comprises aluminum.
